(19) United States
(12) Patent Application Publication
(10) Pub. No.: US 2009/0206431 A1
(43) Pub. Date: Aug. 20, 2009

(54) Imager wafer level module and method of fabrication and use

(75) Inventors: Todd O. Bolken, Eagle, ID (US); Kiran Vanam, Boise, ID (US)

Correspondence Address: DICKSTEIN SHAPIRO LLP, 1825 EYE STREET, NW, WASHINGTON, DC, 20006, US

(73) Assignee: Micron Technology, Inc.

(21) Appl. No.: 12/071,399

(22) Filed: Feb. 20, 2008

(51) Int. Cl. H01L 21/00; H01L 27/00

(52) U.S. Cl. 257/432; 438/65; 257/E21.001; 257/E27.001

(57) ABSTRACT

Imager wafer level modules, methods of assembly for imager wafer level modules, and systems containing imager wafer level modules. An imager die and an optic lens stack are combined to form a module assembly. The module assembly is combined with a molded plastic, laminated plastic, or metallic interposer to form an imager wafer level module capable of assembly using industry standard equipment sets for all processing, and capable of being used with various imaging systems.

### FIELD OF THE INVENTION

The embodiments described herein relate generally to the field of digital imaging, and more specifically to imager wafer level modules, methods for assembling imager wafer level modules, and systems incorporating imager wafer level modules.

### BACKGROUND OF THE INVENTION

Microelectronic imagers are used in digital cameras, wireless devices with picture capabilities, and many other applications. Cellular telephones and Personal Digital Assistants (PDAs), for example, are incorporating microelectronic imagers for capturing and sending pictures. The growth rate of microelectronic imagers has been steadily increasing as they become smaller and produce better images with higher pixel counts.

Microelectronic imagers include image sensors that use Charged Coupled Device (CCD) systems, Complementary Metal-Oxide Semiconductor (CMOS) systems or other imager technology systems. CCD image sensors have been widely used in digital cameras and other applications. CMOS image sensors are quickly becoming very popular because they have low production costs, high yields, and small sizes. CMOS image sensors can provide these advantages because they are manufactured using technology and equipment developed for fabricating semiconductor devices.

One problem experienced in realizing the low production costs and high yields of CMOS imager sensors is adapting the semiconductor industry standard equipment for use with microelectronic imagers. Creating a method of manufacture that reduces the number of steps, while simultaneously allowing the use of industry standard equipment is essential. Specifically, finding an apparatus and method of assembly that: (a) enables the imager and the optics portions of the assembly to be carried through the complete manufacturing process, (b) withstands harsh manufacturing steps, and (c) helps with light direction in the lens, would help lower production costs and increase yields. Accordingly, an imager wafer level module, and imager wafer level module assembly method, that may lower production costs and increase yields is needed.

### BRIEF DESCRIPTIONS OF THE DRAWINGS

FIG. 1 is a cross-sectional expanded view of an imager die and an optic lens stack.

FIG. 2 is a cross-sectional expanded view of the components of an imager wafer level module with a molded plastic interposer.

FIG. 2A is a cross-sectional view of an assembled imager wafer level module with a molded plastic interposer.

FIG. 3 is a cross-sectional expanded view of the components of an imager wafer level module with a plastic laminate interposer.

FIG. 3A is a cross-sectional view of an assembled imager wafer level module with a plastic laminate interposer.

FIG. 4 is a cross-sectional expanded view of the components of an imager wafer level module with a metallic interposer.

FIG. 4A is a cross-sectional view of an assembled imager wafer level module with a metallic interposer.

FIG. 5 is an overhead view of a molded plastic interposer used to assemble an imager wafer level module.

FIG. 6 is an overhead view of a plastic laminate interposer used to assemble an imager wafer level module.

FIG. 7 is an overhead view of a metallic interposer used to assemble an imager wafer level module.

FIG. 8 is an overhead view of the housing used in an imager wafer level module.

FIG. 9 illustrates a system having the imager wafer level modules illustrated in FIGS. 2-4A.

### DETAILED DESCRIPTION OF THE INVENTION

An apparatus and method of assembly using an interposer that can withstand harsh manufacturing steps to enable the imager die and optic lens stack portions of an imager wafer level module to be carried through the complete manufacturing process, can help light guidance, and may help lower production costs while increasing yields.

An interposer is a mounting platform. Embodiments described herein use either a molded plastic, plastic laminate, or metallic interposer. An interposer benefits the apparatus and method of assembly of imager wafer level modules by allowing the components to go through the complete assembly process. Additionally, interposers may enable the process to use industry standard equipment, which may reduce investment in specialized equipment and enable realization of profitability at lower volumes of production. Moreover, production is faster because the interposers will withstand the 260° C. temperature necessary for reflow requirements; allowing the interposers to be used throughout the entire manufacturing process and eliminating the step of removing them. The disclosed interposers have structural benefits, which include the ability to be specifically formed for the situation. This allows an interposer to have either an aperture, or an aperture with an interposer light guide to discriminate between light which should pass through the interposer light guide, and light that should not. The interposer also helps prevent electromagnetic interference. The interposer, in combination with a housing, serves to shield or block any electromagnetic emissions from other sources (e.g. antennas or other devices in a cell phone) or the imager itself. Blocking electromagnetic interference allows better performance of the imager wafer level module. In each embodiment described herein, subject to the specific characteristics of the interposer material, these benefits are realized by using an interposer in the assembly process, maintaining the interposer as part of the final imager wafer level module, and installing a housing.

In the following detailed description, reference is made to the accompanying drawings which form a part hereof, and in which is shown by way of illustration specific embodiments that may be practiced. It should be understood that like reference numerals represent like elements throughout the drawings. These example embodiments are described in sufficient detail to enable those skilled in the art to practice them. It is to be understood that other embodiments may be utilized, and that structural, logical, and electrical changes may be made.

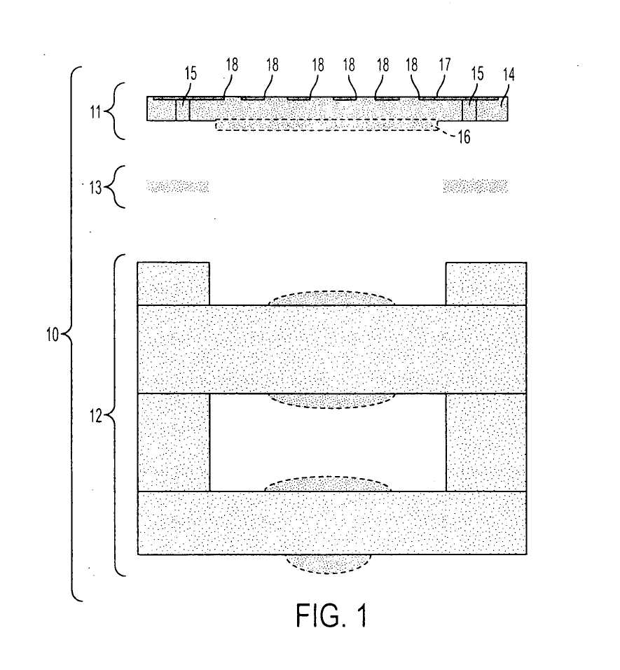

Referring to FIGS. 1-4A, embodiments described herein use fastening substances 13, 22, 23, 25 to affix components. Where a fastening substance 13, 22, 23, 25 is referenced in the below description, it should be understood that any adhesive, solder, or any other appropriate substance or method understood by those skilled in the art as being capable of affixing the subject components is included. Additionally, where “finalizing” a fastening substance 13, 22, 23, 25 is referenced in the below description, it should be understood that any fastening substance 13, 22, 23, 25 as defined above, is receiving the necessary steps to make its respective bond permanent. Examples of “finalizing” steps include, but are not limited to, curing adhesives, and reflowing solders.

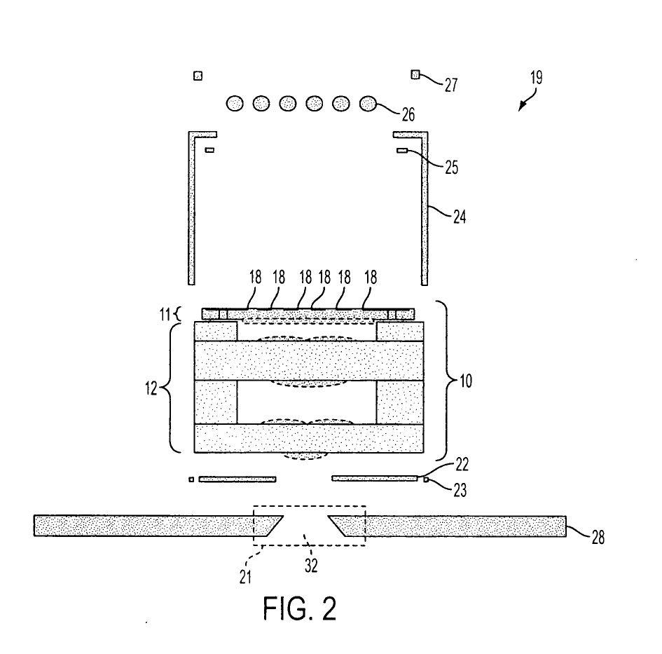

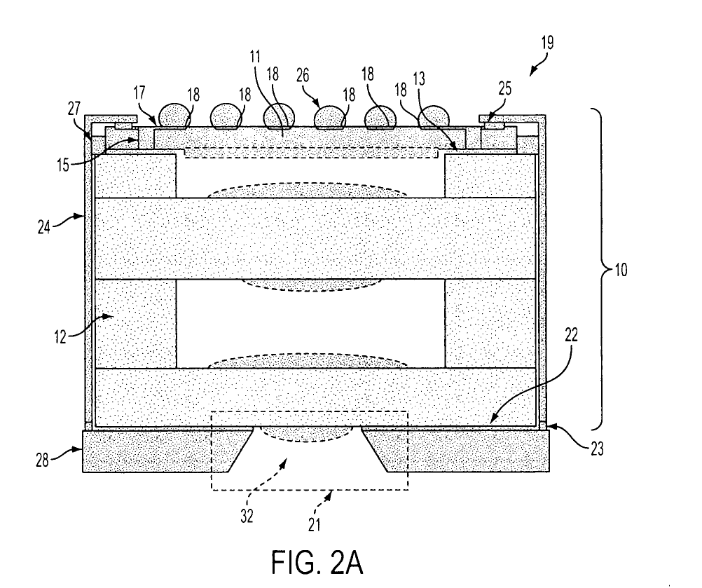

Referring now to the specific embodiments described herein, FIG. 1 is a cross-sectional expanded view of a module assembly 10 made up of an imager die 11 and an optic lens stack 12. This module assembly 10 is a component of all illustrated embodiments of the imager wafer level module 19, 19′, 19″ (FIGS. 2-4A). The imager die 11 includes an imager 16 which may be a charge coupled device (CCD), complementary metal-oxide-semiconductor (CMOS), or any other type of imager, a substrate 14, vias 15, a re-distribution layer (“RDL”) 17, and ball bond pads 18. The optic lens stack 12 conveys an image to the imager 16. The optic lens stack 12 is shown with four lenses, but may have more or fewer lenses in this or other configurations as is known in the art. The vias 15 are formed through the substrate 14 to create a circuitry path to the re-distribution layer 17 and the ball bond pads 18. The optic lens stack 12 is fastened to the imager die 11 with an imager die to optic lens stack fastening substance 13.

In a first method of assembly, assembling a module assembly 10 includes combining a single imager die 11 with a single optic lens stack 12 to form a single module assembly 10. Both the imager die 11 and the optic lens stack 12 may be assembled by methods well known in the art. The imager die 11, prior to being used in an imager wafer level module 19, 19′, 19″ (FIGS. 2-4A), will be thinned to about 100 μm. In the illustrated module assembly 10, an individual optic lens stack 12 is placed on an individual imager die 11 to form a single module assembly 10. In most cases, a plurality of imager dies 11 will have been previously assembled on a wafer and diced by a wafer saw to create separations so that individual imager dies 11 can be used as a component in a module assembly 10. Similarly, in most cases, a plurality of optic lens stacks 12 will have been previously assembled and diced by a wafer saw to create separations so that individual optic lens stacks 12 can be used as a component in a module assembly 10. In the first method of assembly, the imager die 11 is fastened to the optics lens stack 12 using an imager die to optic lens stack fastening substance 13 such that an image can pass through the optic lens stack 12 to the imager 16. This single module assembly 10 can be used as a component in assembling an imager wafer level module 19, 19′, 19″ (FIGS. 2-4A).

In a second method of assembly, assembling the module assembly 10 includes combining a plurality of imager dies 11 with a plurality of optic lens stacks 12 to form a plurality of module assemblies 10. This is accomplished by not performing the dicing steps of the first method of assembly, and leaving both the plurality of imager dies 11 and the plurality of optic lens stacks 12 on their respective wafers. A wafer containing a plurality of optic lens stacks 12 is aligned and fastened to a wafer containing a plurality of imager dies 11, using an imager die to optic lens stack fastening substance 13, such that an image can pass through the optic lens stack 12 to the imager 16.

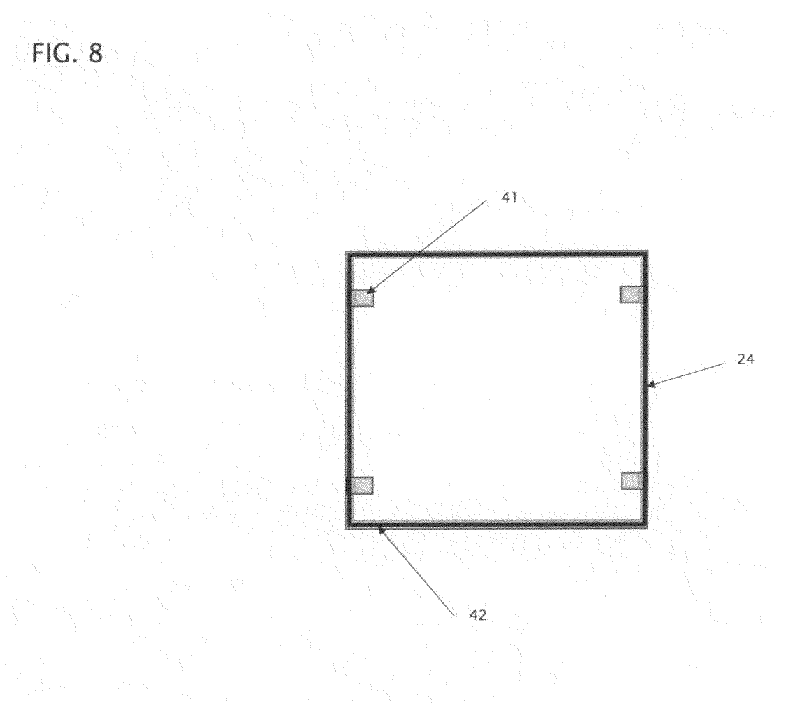

Referring now to FIG. 2, which is a cross-sectional expanded view of the components of an imager wafer level module 19 with a molded plastic interposer 28 in accordance with an embodiment described herein. An optic lens stack to interposer fastening substance 22 fastens the molded plastic interposer 28 to the optic lens stack 12 portion of the module assembly 10. A housing to imager die fastening substance 25 is applied to a module assembly 10 to attach a housing 24 to the module assembly 10. The housing 24 has a perimeter shape that encloses the imager die assembly 11 and optic lens stack assembly 12. A housing to interposer fastening substance 23 is used to fasten the housing 24 to the molded plastic interposer 28. FIG. 8 is an overhead view of the housing 24. The housing 24, for embodiments where solder is used for either or both of housing to imager die fastening substance 25 and housing to interposer fastening substance 23, has specific types of solder control plating 41, 42. When solder is used for housing to imager die fastening substance 25, the housing 24 has ground pad solder control plating 41. When solder is used for housing to interposer fastening substance 23, the housing 24 has interposer attach solder control plating 42. When solder is used for the housing to imager die fastening substance 25, plating 41 is used to control the flow of solder during its placement to ensure that the housing to imager die fastening substance 25—which in this case is solder—stays in areas that will facilitate effective fastening of the housing 24 to the molded plastic interposer 28. When solder is used for the housing to interposer fastening substance 23, plating 42 is used to control the flow of solder during the housing's 24 placement to ensure that the housing to interposer fastening substance 23—which in this case is solder—stays in areas that will facilitate effective fastening of the molded plastic interposer 28 to the housing 24.

The molded plastic interposer 28 includes an aperture 32. An aperture 32 is merely an unfilled space in the interposer 28 that is not specifically designed to direct light in conjunction with the design of the imager wafer level module 19. Every embodiment must have an aperture 32 to allow an image to pass to the imager 16 (FIG. 1). In other embodiments, the interposer 28 will include an optional interposer light guide 21, in addition to an aperture 32. An interposer light guide 21 is specifically designed to discriminate between light that should pass through the interposer light guide 21 to the imager 16 (via optic lens stack 12) (FIG. 1), and light that should not.

Pre-formed solder balls 26 may be dispensed to ball bond pads 18 of the imager die 11. Pre-formed solder balls allow for connecting the imager wafer level module 19 to another apparatus. Liquid encapsulation 27 is used to surround a perimeter of the imager die 11 and serves the dual purposes of light shielding and enhancing imager wafer level module 19 integrity.

FIG. 2A is a cross-sectional view of an assembled imager wafer level module 19 with the molded plastic interposer 28. FIG. 2A is similar to FIG. 2, but shows the final location of each component of the imager wafer level module 19, as opposed to the expanded view of FIG. 2. Specifically, FIG. 2A shows the molded plastic interposer 28, formed with an aperture 32 by any available method. The molded plastic interposer 28 is fastened to the optic lens stack 12 portion of the module assembly 10 with optic lens stack to interposer fastening substance 22 such that an image can pass through aperture 32, interposer light guide 21 (if included), and lens stack assembly 12 to the imager 16 (FIG. 1). The housing 24 is attached to the imager die 11 portion of the module assembly 10 with housing to imager die fastening substance 25. The housing 24 is fastened to the molded plastic interposer 28 with a housing to interposer fastening substance 23. The imager die 11 contains vias 15 extending to the re-distribution layer 17. The vias 15 create a circuitry path through the ball bond pads 18 to the pre-formed solder balls 26 attached to the ball bond pads 18. Additionally, imager die to optic lens stack fastening substance 13 is shown between the imager die 11 and optic lens stack 12. Liquid encapsulation 27 surrounds the perimeter of the imager die 11.

Referring to FIGS. 2 and 2A, the imager wafer level module 19 is constructed as follows. Once individual module assemblies 10, or a plurality of module assemblies 10 on a wafer, have been created, imager wafer level modules 19 with a molded plastic interposer 28 can be assembled. The module assembly 10 is fastened to the molded plastic interposer 28 using optic lens stack to interposer fastening substance 22. The optic lens stack to interposer fastening substance 22 must be “finalized” depending on which fastening substance is used. It should be noted that any suitable fastening substance 22 or method known in the art may be used. The housing 24 is fastened to the molded plastic interposer 28 and the imager die 11 portion of the module assembly 10 by housing to interposer fastening substance 23 and housing to imager die fastening substance 25, respectively. Housing to interposer fastening substance 23 and housing to imager die fastening substance 25 may require finalizing depending on which fastening substance is used, but any suitable fastening substance or method known in the art may be used.

The order of placement of the fastening substances 22, 23, 25 is not fixed. All fastening substances 22, 23, 25 may be laid simultaneously followed by sequential placement of the module assembly 10 and the housing 24. Alternatively, as an example only and not intended to be limiting, fastening substance 22 alone may be placed, followed by module assembly 10 placement, placement of fastening substances 23 and 25, and followed by housing 24 placement.

The module assembly 10 should be placed on its corresponding fastening substance 22 prior to housing 24 placement on its housing-associated fastening substances 23, 25. The module assembly 10 should be placed on the molded plastic interposer 28 in a position whereby the previously placed optic lens stack to interposer fastening substance 22 will allow for fastening the module assembly 10 to the molded plastic interposer 28. Additionally, the module assembly 10 should be placed such that an image can pass through the aperture 32, through the interposer light guide 21 (if included), and the optic lens stack 12, to the imager 16. The housing 24 can only be placed on the molded plastic interposer 28 after the module assembly 10 has been placed on the molded plastic interposer 28. The housing 24 must be placed on the molded plastic interposer 28 in a position whereby the previously placed fastening substances 23, 25 will allow for the fastening of the housing 24 to the molded plastic interposer 28 and the imager die 11 portion of the module assembly 10.

Additionally, pre-formed solder balls 26 can be dispensed to the ball bond pads 18 of the optic lens stack 12. The pre-formed solder balls 26, and fastening substances 13, 22, 23, 25 must be finalized where appropriate. The order of finalizing fastening substances 13, 22, 23, 25 in embodiments where such fastening substances 13, 22, 23, 25 are used, is not fixed. Finalizing fastening substances 13, 22, 23, 25 can occur in series or simultaneously. For example, and not intended to be limiting, optic lens stack to interposer fastening substance 22 can be finalized after the placement of the module assembly 10 on the molded plastic interposer 28. Alternatively, optic lens stack to interposer fastening substance 22 can be finalized simultaneously with both the housing to interposer and housing to imager die fastening substances 23, 25 after placement of the housing 24. Moreover, simultaneous finalizing may occur with the finalizing of solder balls 26 or the finalizing of imager die to optic lens fastening substance 13 in embodiments where finalizing either or both of these elements is required.

A liquid encapsulation 27 is also applied to the imager die 11 portion of the module assembly 10. Liquid encapsulation 27, serves the dual purposes of light shielding and enhancing imager wafer level module 19 integrity. Light shielding serves to prevent errant light from impacting the output of the imager die 11 thereby ensuring that all light reaching the imager die 11 has been properly channeled through the optic lens stack 12. The liquid encapsulation 27 also serves as a stabilizer by filling space between the housing 24 and the imager die 11. This space would otherwise be subject to collapse, or other types of damage.

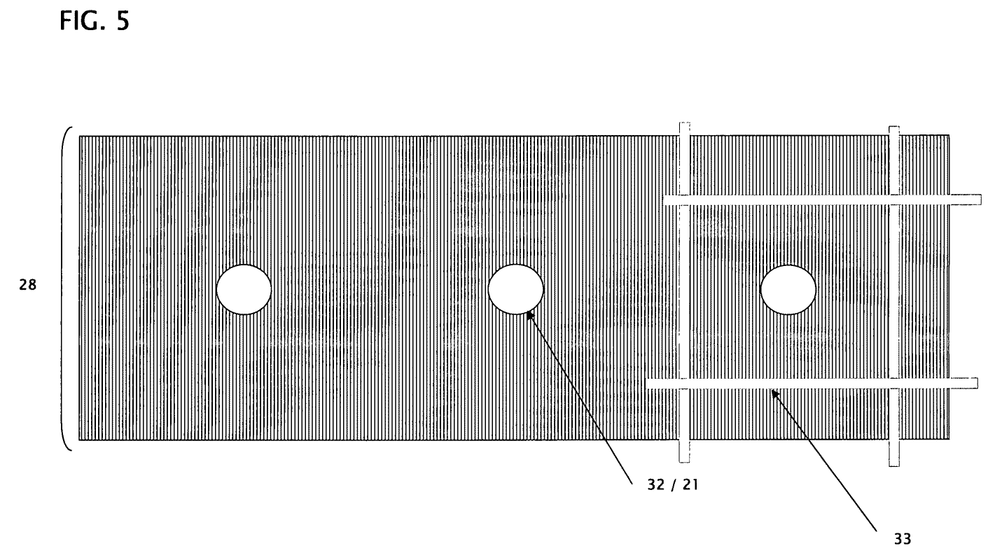

Once a plurality of imager wafer level modules 19 have been assembled on a molded plastic interposer 28, the plurality of imager wafer level modules 19 can be separated into individual imager wafer level modules 19, or groups of imager wafer level modules 19 as required for a specific application. This process of separation is known as singulation. FIG. 5 is an overhead view of a representative molded plastic interposer 28, with representative saw streets 33, which can be used by a saw to singulate individual imager wafer level modules 19 from a plurality of wafer level modules 19. For example, and not intended to be limiting, in FIG. 5 three module assemblies could be placed over the three apertures 32. As presented previously, these three module assemblies 10 could be assembled by either of two methods. In a first embodiment, module assemblies 10 could be assembled as individual module assemblies 10 and placed individually over their respective apertures 32 such that light would pass through the aperture, through the optic lens stack 12, to the imager 16 of the imager die 11. Alternatively, the three module assemblies 10 could be assembled as a group and placed over respective apertures 32 such that light would pass to the imager 16 (FIG. 1). With either method of assembly, singulation is required. Singulating imager wafer level modules 19 having a molded plastic interposer 28 requires dicing using a saw. Once singulating is completed, the imager wafer level modules 19 may be either tested or placed in trays for shipment.

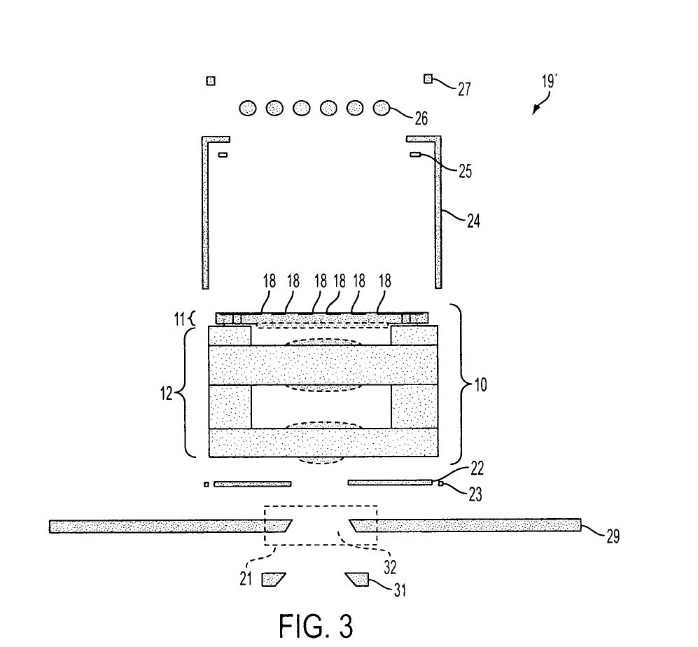

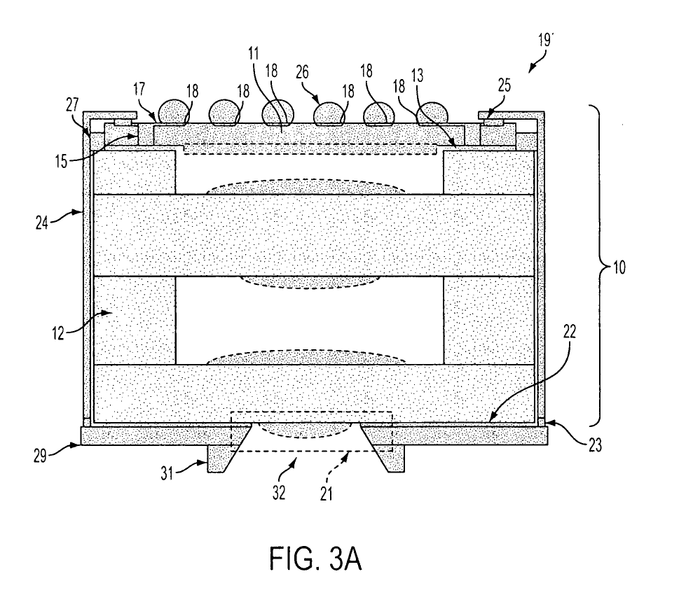

FIG. 3 is a cross-sectional expanded view of the components of a second embodiment imager wafer level module 19′ with a plastic laminate interposer 29. Elements in FIG. 3 referring to like elements in FIGS. 1-2A have the same reference numerals. In the illustrated embodiment, a light guide 31 may also be included. Whether or not an interposer light guide 21 is present with the required aperture 32, the imager wafer level module 19′ may also have light guide 31. This light guide 31, similar to the interposer light guide 21, is used to discriminate between light that should pass, and light that should not pass to the imager 16 (FIG. 1) of the module assembly 10.

FIG. 3A is a cross-sectional view of an assembled imager wafer level module 19′ with the plastic laminate interposer 29. The components within FIG. 3A are arranged identical to those found in FIG. 2A, with the addition of optional light guide 31 attached to the plastic laminate interposer 29.

Referring to FIGS. 3 and 3A, the imager wafer level module 19′ is constructed as presented for FIGS. 2 and 2A, with the following exception. Imager wafer level module 19′ may also include a light guide 31 which could be used alone, or in combination with an interposer light guide 21, to pass light through the aperture 32 and optic lens stack 12 to the imager 16 (FIG. 1).

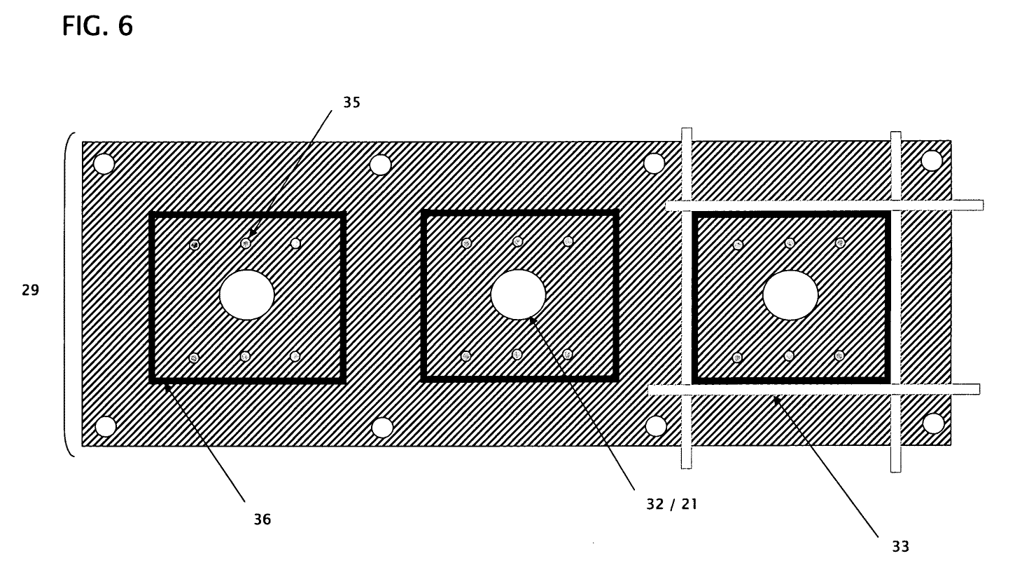

FIG. 6 is an overhead view of a representative plastic laminate interposer 29. The plastic laminate interposer 29 has representative saw streets 33, which are used as presented for FIG. 5. FIG. 6 also depicts two types of solder control plating used in embodiments when solder is used for one or both of optic lens stack to interposer fastening substance 22 and housing to interposer fastening substance 23. When solder is used for the optic lens stack to interposer fastening substance 22, plating 35 is used to control the flow of solder during optic lens stack 12 placement to ensure that the optic lens stack to interposer fastening substance 22—which in this case is solder—stays in areas that will facilitate effective fastening of the plastic laminate interposer 29 to the optic lens stack 12 portion of the module assembly 10. When solder is used for the housing to interposer fastening substance 23, plating 36 is used to control the flow of solder during housing 24 placement to ensure that the housing to interposer fastening substance 23—which in this case is solder—stays in areas that will facilitate effective fastening of the plastic laminate interposer 29 to the housing 24.

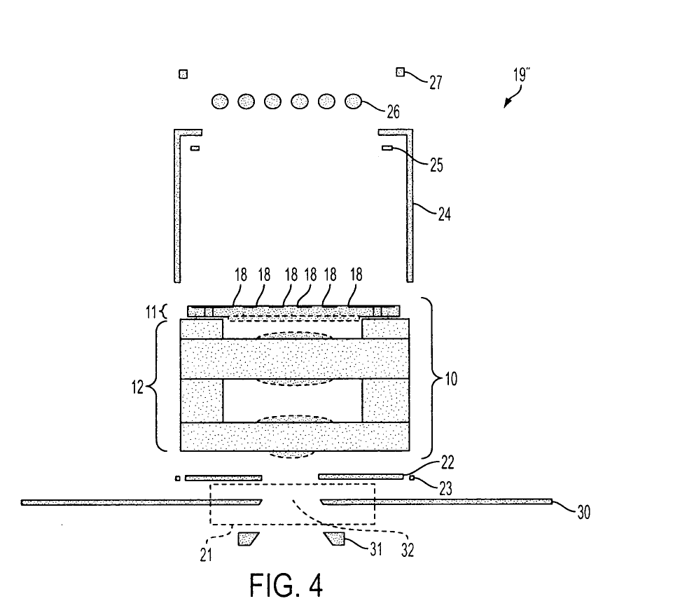

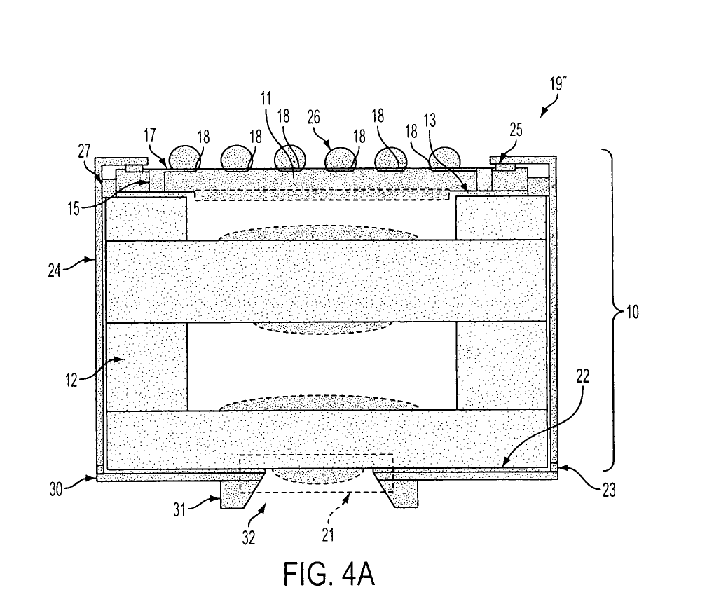

FIG. 4 is a cross-sectional expanded view of the components of another embodiment imager wafer level module 19″ with a metallic interposer 30. The components within FIG. 4 are arranged identical to those found in FIG. 3.

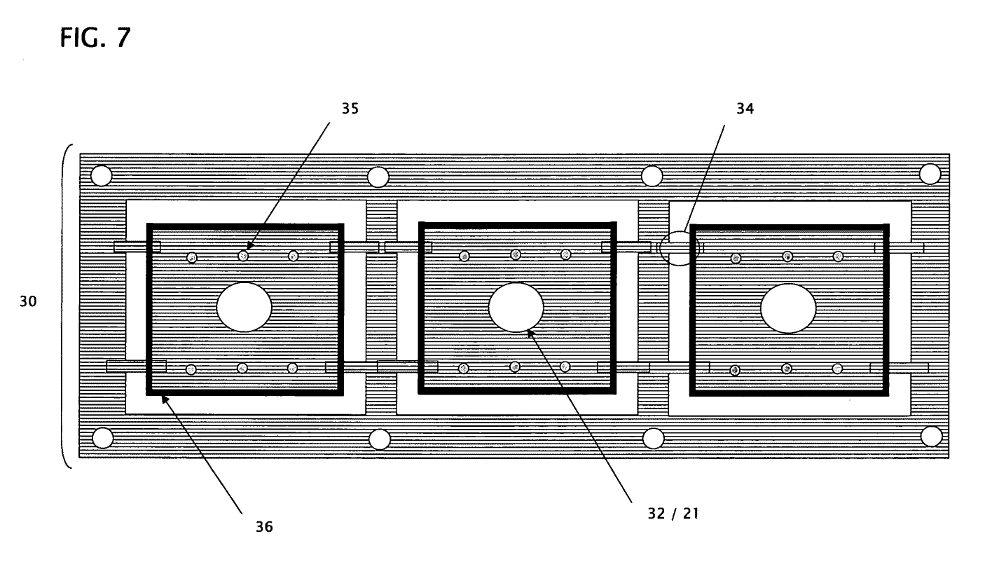

FIG. 4A is a cross-sectional view of an assembled imager wafer level module 19″ with the metallic interposer 30. The components within FIG. 4A are arranged identically to those found in FIG. 3A. Referring to FIGS. 4 and 4A, the imager wafer level module 19′ is constructed as presented for FIGS. 3 and 3A with the following exception. Referring to FIG. 7, an overhead view of a representative metallic interposer 30, the process of singulating modules 19″ having a metallic interposer 30 requires punching the tie bars 34 and trimming and forming the metallic interposer 30. The two types of solder control plating in FIG. 7 are as presented for FIG. 6.

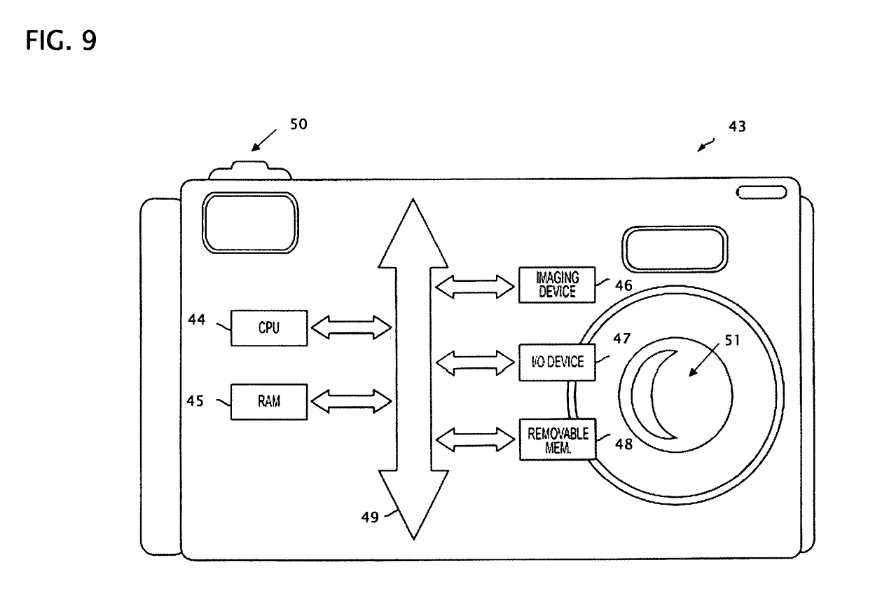

Referring to FIG. 9, a typical system 43, such as, for example, a camera is displayed. The system 43 includes an imaging device 46 having an imager wafer level module 19, 19′, 19″. The system 43 is an example of a system having digital circuits that could include image sensor devices. Without being limiting, such a system could include a computer system, camera system, scanner, machine vision, vehicle navigation system, video phone, surveillance system, auto focus system, star tracker system, motion detection system, image stabilization system, and other systems employing an imager.

System 43, for example, a camera system, includes a lens 51 for focusing an image when a shutter release button 50 is pressed. System 43 generally comprises a central processing unit (CPU) 44, such as a microprocessor that controls camera functions and image flow, and communicates with an input/output (I/O) device 27 over a bus 49. The imaging device 46 also communicates with the central processing unit 44 over the bus 49. The processor-based system 43 also includes random access memory (RAM) 45, and can include removable memory 48, such as flash memory, which also communicates with the central processing unit 44 over the bus 49. The imaging device 46 may be combined with the central processing unit 44, with or without memory storage on a single integrated circuit or on a different chip than the central processing unit 44.

It should again be noted that although the embodiments have been described with specific references to imager wafer level modules 19, 19′, 19″ intended for light capture, the embodiments have broader applicability and may be used in any imaging apparatus, including those that require image display. For example, without limitation, embodiments may be used in conjunction with Liquid Crystal Display (LCD) technologies. In addition, although an example of use of the optical packages with CMOS image sensors have been given, the invention has applicability to other image sensors, as well as display devices.

The above description and drawings illustrate embodiments which achieve the objects, features, and advantages described. Although certain advantages and embodiments have been described above, those skilled in the art will recognize that substitutions, additions, deletions, modifications and/or other changes may be made.

What is claimed as new and desired to be protected by Letters Patent of the United States is:

1. A method of assembling an imager wafer level module comprising:
forming a module assembly comprising an imager die and optic lens stack;
fastening the module assembly to the interposer using a first fastening substance;
fastening a housing to the module assembly using a second fastening substance; and
fastening the housing to the interposer using a third fastening substance.

2. The method of claim 1, wherein the imager die is assembled by:
mounting a plurality of imagers on a wafer; and
dicing the plurality of imagers into a plurality of imager dies.

3. The method of claim 1, wherein the optic lens stack is assembled by:
mounting a plurality of optic lenses on a wafer; and
dicing the plurality of optic lenses into a plurality of optic lens stacks.

4. The method of claim 1, wherein forming a module assembly comprises:
forming a plurality of imager dies on a first wafer;
forming a plurality of optic lens stacks on a second wafer;
arranging the first and second wafers such that light may pass through the plurality of optic lens stacks to an imager of each of the plurality of imager dies; and
fastening the first and second wafers together.

5. The method of claim 1, wherein forming a module assembly comprises:
selecting an imager die and placing the imager die on a carrier;
selecting an optic lens stack and placing the optic lens stack on the imager die; and
fastening the optic lens stack to the imager die with a fastening substance.

6. The method of claim 1, wherein the second and third fastening substances are selected from the group consisting of solder paste and conductive epoxy.

7. The method of claim 1 further comprising fastening a light guide to the interposer.

8. The method of claim 1, wherein the interposer is molded to include an interposer light guide.

9. The method of claim 1, wherein the interposer comprises material selected from the group consisting of molded plastic, plastic laminate, and metals.

10. The method of claim 1 further comprising:
applying liquid encapsulation to a perimeter of the imager die;
dispensing a plurality of solder balls to the module assembly; and
separating individual imager wafer level modules.

11. The method of claim 1, wherein the interposer is a molded plastic interposer, the first and third fastening substances are adhesive, the housing is adhered to the molded plastic interposer, and the module assembly is adhered to the molded plastic interposer.

12. The method of claim 1, wherein the interposer is a molded plastic interposer, the first fastening substance comprises adhesive, the third fastening substance comprises solder, the module assembly is adhered to the molded plastic interposer, and the housing is soldered to the molded plastic interposer

13. The method of claim 1, wherein the interposer is plastic laminate, the first fastening substance comprises a first solder paste pattern, the third fastening substance comprises a second solder paste pattern, the module assembly is soldered to the plastic laminate interposer with the first solder paste pattern, and the housing is soldered to the plastic laminate interposer with the second solder paste pattern.

14. The method of claim 1, wherein the interposer is plastic laminate, the first fastening substance comprises an adhesive, the third fastening substance comprises a solder paste pattern, the module assembly is adhered to the plastic laminate interposer, and the housing is soldered to the plastic laminate interposer.

15. The method of claim 1, wherein the interposer is metallic, the first fastening substance comprises a first solder paste pattern, the third fastening substance comprises a second solder paste pattern, the module assembly is soldered to the metallic interposer with the first solder paste pattern, and the housing is soldered to the metallic interposer with the second solder paste pattern.

16. The method of claim 1, wherein the interposer is metallic, the first fastening substance comprises an adhesive, the third fastening substance comprises a solder paste pattern, the module assembly is adhered to the metallic interposer, and the housing is soldered to the metallic interposer.

17. An apparatus comprising:
an imager die assembly;
an optic lens stack fastened to the imager die by a first fastening substance;
a housing fastened to the imager die by a second fastening substance; and
an interposer fastened to the housing by a third fastening substance, the interposer fastened to the optic lens stack by a fourth fastening substance.

18. The apparatus of claim 17, wherein the second fastening substance is selected from the group consisting of solder paste and conductive epoxy.

19. The apparatus of claim 17 further comprising:
a plurality of solder balls fastened to the imager die assembly; and
liquid encapsulation encapsulating the perimeter of the imager die assembly.

20. The apparatus of claim 17, wherein the interposer comprises material selected from the group consisting of molded plastic, plastic laminate, and metals.

21. The apparatus of claim 17, wherein the housing further comprises a plurality of tabs for attaching the housing to the imager die.

22. The apparatus of claim 21, wherein the housing further comprises ground pad solder control plating and interposer attach solder control plating.

23. The apparatus of claim 17, wherein the interposer further comprises:
an aperture;
an interposer light guide;
lens attach solder control plating;
housing attach solder control plating; and
an interposer singulation track.

24. A camera system, comprising:
an imaging device comprising an imager wafer level module assembly comprising:
an imager die assembly;
an optic lens stack fastened to the imager die by a first fastening substance;
a housing fastened to the imager die by a second fastening substance; and
an interposer fastened to the optic lens stack by a third fastening substance, the interposer fastened to the housing by a fourth fastening substance.

25. The system of claim 24, wherein the interposer is selected from the group consisting of a molded plastic interposer, a plastic laminate interposer, and a metallic interposer.
